(19) United States
(12) Patent Application Publication
(10) Pub. No.: US 2017/0194212 A1
(43) Pub. Date: Jul. 6, 2017

(54) SEMICONDUCTOR DEVICE AND METHOD FOR FABRIACTING THE SAME

(71) Applicant: UNITED MICROELECTRONICS CORP., Hsin-Chu City (TW)

(72) Inventors: Ching-Wen Hung, Tainan City (TW); Ying-Cheng Liu, Tainan City (TW); Jia-Rong Wu, Kaohsiung City (TW); Yi-Hui Lee, Taipei City (TW); Chih-Sen Huang, Tainan City (TW)

(21) Appl. No.: 15/008,462

(22) Filed: Jan. 28, 2016

(30) Foreign Application Priority Data
Jan. 6, 2016 (TW) 105100229

(51) Int. Cl. H01L 21/8238; H01L 29/161; H01L 27/092; H01L 29/24; H01L 29/165; H01L 29/78; H01L 29/08; H01L 29/16

(52) U.S. Cl. CPC H01L 21/823814; H01L 21/823821; H01L 21/823878; H01L 21/823871; H01L 29/0847; H01L 29/161; H01L 29/1608; H01L 29/24; H01L 29/165; H01L 29/7848; H01L 27/0924

(57) ABSTRACT

A method for fabricating semiconductor device is disclosed. The method includes the steps of: providing a substrate; forming a first fin-shaped structure and a second fin-shaped structure on the substrate; forming a first epitaxial layer on the first fin-shaped structure and a second epitaxial layer on the second fin-shaped structure; and forming a cap layer on the first epitaxial layer and the second epitaxial layer. Preferably, a distance between the first epitaxial layer and the second epitaxial layer is between twice the thickness of the cap layer and four times the thickness of the cap layer.

### BACKGROUND OF THE INVENTION

1. Field of the Invention

The invention relates to a method for fabricating semiconductor device, and more particularly, to a method of remaining a cap layer between epitaxial layer and shallow trench isolation (STI) during the formation of contact holes.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the FinFET can be controlled by adjusting the work function of the gate.

However, numerous problems still arise from the integration of fin-shaped structure and epitaxial layer in today's FinFET fabrication and affect current leakage and overall performance of the device. Hence, how to improve the current FinFET process has become an important task in this field.

### SUMMARY OF THE INVENTION

According to a preferred embodiment of the present invention, a method for fabricating semiconductor device is disclosed. The method includes the steps of: providing a substrate; forming a first fin-shaped structure and a second fin-shaped structure on the substrate; forming a first epitaxial layer on the first fin-shaped structure and a second epitaxial layer on the second fin-shaped structure; and forming a cap layer on the first epitaxial layer and the second epitaxial layer. Preferably, a distance between the first epitaxial layer and the second epitaxial layer is between twice the thickness of the cap layer and four times the thickness of the cap layer.

According to another aspect of the present invention, a semiconductor device is disclosed. The semiconductor device includes: a substrate; a fin-shaped structure on the substrate; a shallow trench isolation (STI) on the substrate and around the fin-shaped structure; an epitaxial layer on the fin-shaped structure; and a cap layer between the epitaxial layer and the STI.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view diagram of a semiconductor device according to a preferred embodiment of the present invention.

FIGS. 2-3 illustrate 3-dimensional views for fabricating a semiconductor device according an embodiment of the present invention.

FIGS. 4-6 illustrate cross-sectional views of FIG. 3 along sectional line AA′.

FIG. 7 is a top view diagram of a semiconductor device according to an embodiment of the present invention.

### DETAILED DESCRIPTION

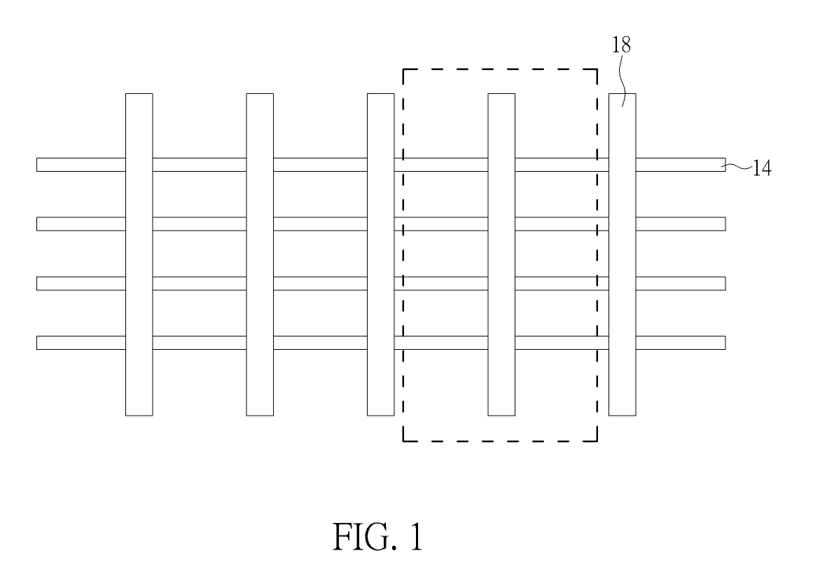

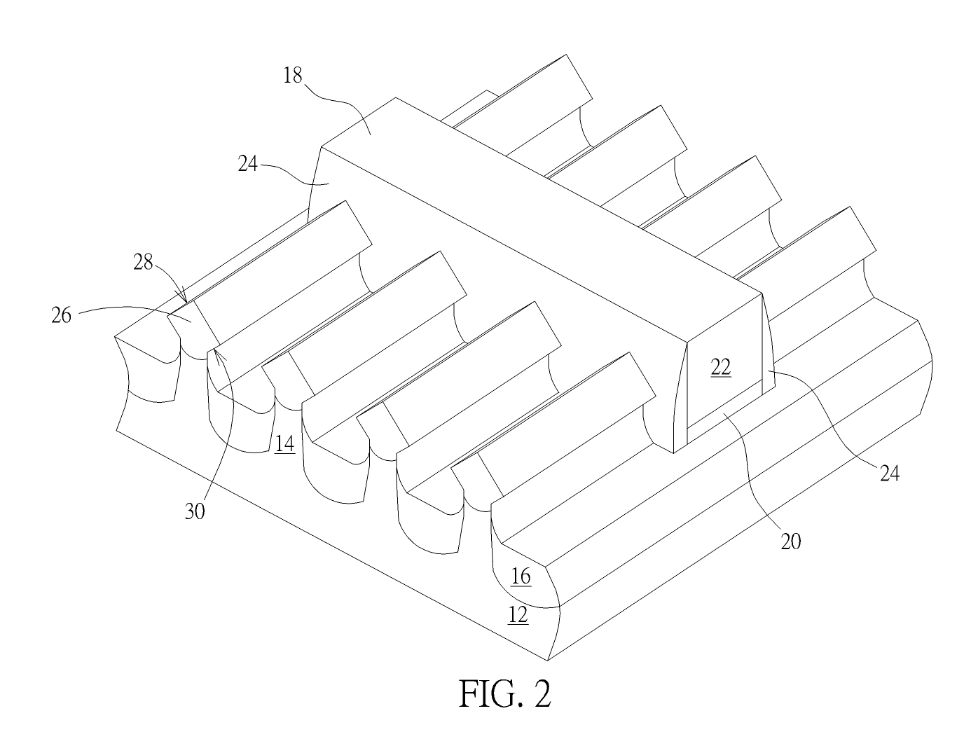

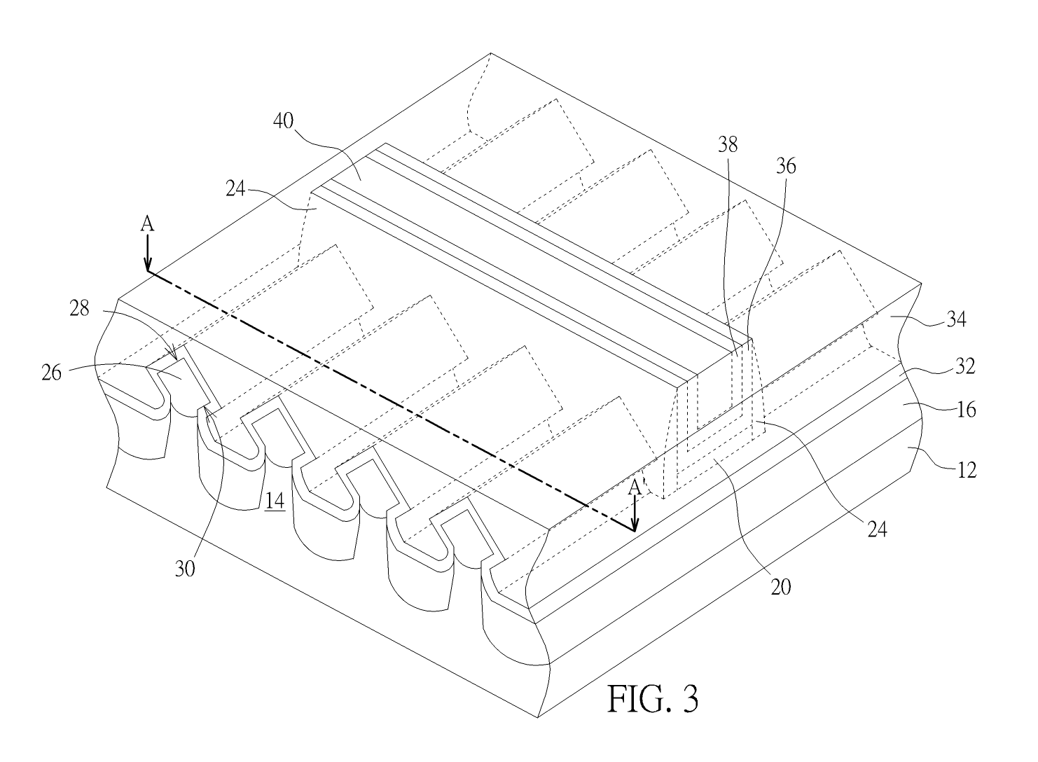

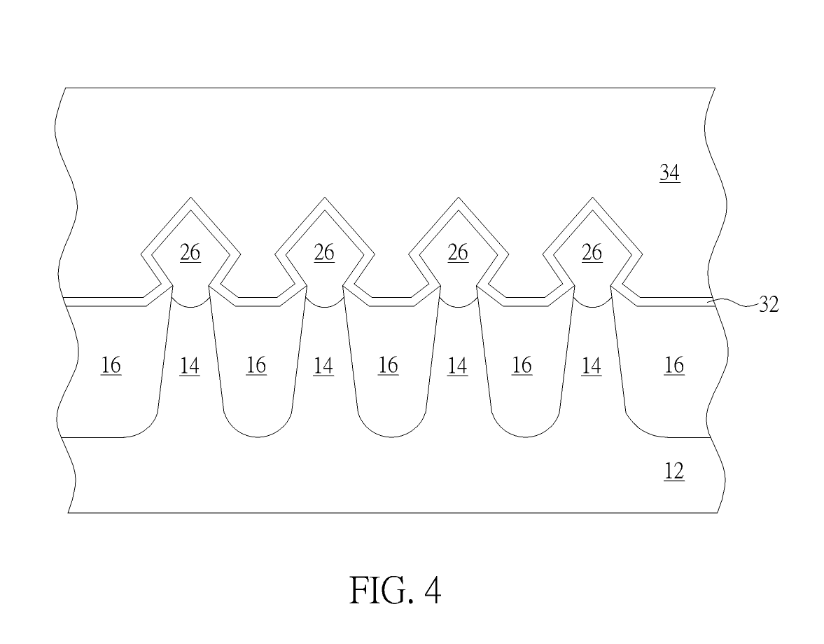

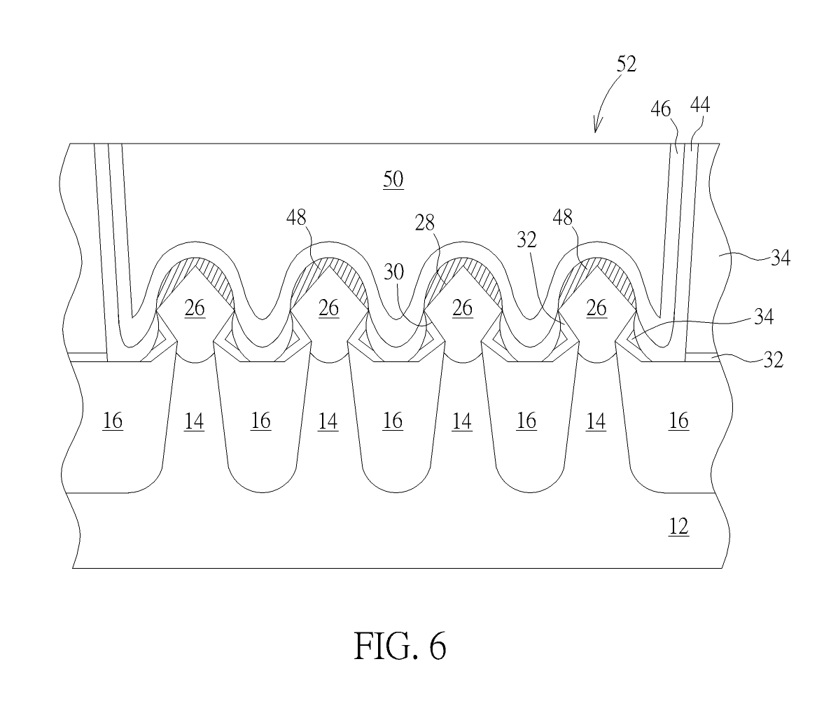

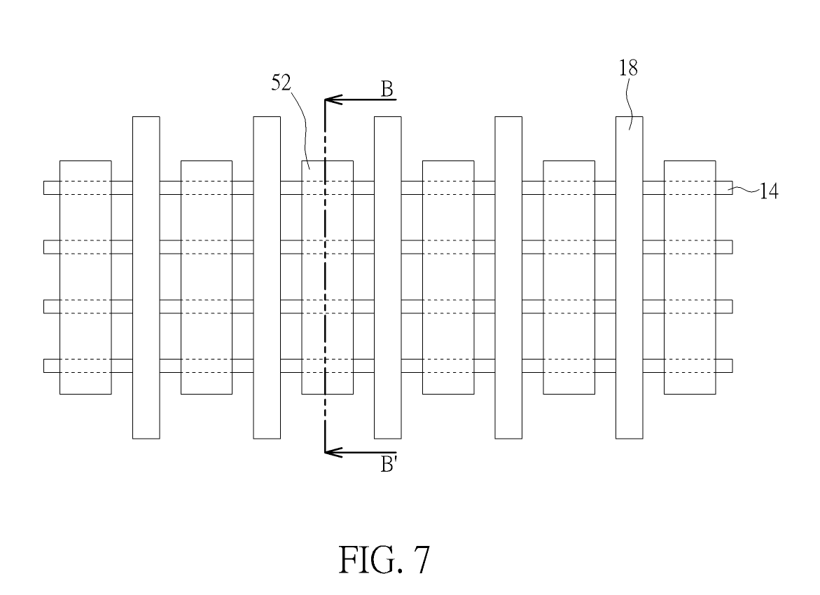

Referring to FIGS. 1-7, FIGS. 1-7 illustrate a method for fabricating semiconductor device according to a preferred embodiment of the present invention, in which FIG. 2 illustrates a 3-dimensional view of FIG. 1 along the dotted line, FIGS. 2-3 illustrate 3-dimensional views for fabricating a semiconductor device, FIGS. 4-6 illustrate cross-sectional views of FIG. 3 along sectional line AA′, and FIG. 6 illustrates a cross-sectional view of FIG. 7 along sectional line BB′.

As shown in FIGS. 1-2, a substrate 12, such as a silicon substrate or silicon-on-insulator (SOI) substrate is provided, and a transistor region, such as NMOS region is defined on the substrate 12. At least a fin-shaped structure 14 and an insulating layer (not shown) are formed on the substrate 12, in which the bottom of the fin-shaped structures 14 is preferably enclosed by the insulating layer, such as silicon oxide to form a shallow trench isolation (STI) 16, and dummy gates or gate structures 18 are formed on part of the fin-shaped structures 14. It should be noted that to emphasize the structural views of fin-shaped structure and gate structure, only a single gate structure crossing multiple fin-shaped structures are shown in FIG. 2 of this embodiment.

The formation of the fin-shaped structures 14 could be accomplished by first forming a patterned mask (now shown) on the substrate, 12, and an etching process is performed to transfer the pattern of the patterned mask to the substrate 12. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form a STI surrounding the bottom of the fin-shaped structures 14. Alternatively, the formation of the fin-shaped structures 14 could be accomplished by first forming a patterned hard mask (not shown) on the substrate 12, and then performing an epitaxial process on the exposed substrate 12 through the patterned hard mask to grow a semiconductor layer. This semiconductor layer could then be used as the corresponding fin-shaped structures 14, the patterned hard mask could be removed selectively or retained, and deposition, CMP, and then etching back could be used to form a STI surrounding the bottom of the fin-shaped structures 14. In another fashion, if the substrate 12 were a SOI substrate, a patterned mask could be used to etch a semiconductor layer on the substrate until reaching a bottom oxide layer underneath the semiconductor layer to form the corresponding fin-shaped structure. If this means is chosen the aforementioned steps for fabricating the STI could be eliminated.

The formation of the gate structure 18 could be accomplished by a gate first process, a high-k first approach from gate last process, or a high-k last approach from gate last process. Since this embodiment pertains to a high-k last approach, a gate structure 18 composed of interfacial layer 20 and polysilicon gate 22 is formed on the fin-shaped structures 14, and a spacer 24 is formed on sidewalls of the gate structure 18. In this embodiment, the spacer 24 could be a single spacer or a composite spacer, in which the spacer 24 is selected from the group consisting of SiO₂, SiN, SiON, and SiCN, but not limited thereto.

Next, part of the fin-shaped structures 14 is removed and an epitaxial growth process is conducted to form an epitaxial layer 26 on each of the fin-shaped structures 14 adjacent to two sides of the gate structure 18. Depending on the type of transistor being fabricated, the epitaxial layers 26 could be selected from the group consisting of SiGe, SiC, and SiP. It should be noted that each of the epitaxial layers 26 formed on the fin-shaped structures 14 has a substantially rhombus shape, in which each of the epitaxial layers 26 further includes a reverse V-shaped top surface 28 and a V-shaped bottom surface 30.

Next, as shown in FIGS. 3-4, a cap layer 32 is formed on the epitaxial layers 26, in which the cap layer 32 is preferably a contact etch stop layer (CESL) having stress, and the cap layer 32 is preferably selected from the group consisting of SiN, SiCN, and SiCON. In this embodiment, a distance between two adjacent epitaxial layers 32 is preferably between twice the thickness of the cap layer 32 to four times the thickness of the cap layer 32.

Next, a dielectric layer 34 or interlayer dielectric (ILD) layer is formed on the cap layer 32, STI 16, and fin-shaped structures 14, and a planarizing process such as CMP is conducted to remove part of the dielectric layer 34 and part of the cap layer 32 to expose the gate electrode composed of polysilicon material 22 so that the top surface of the gate electrode is even with the top surface of the dielectric layer 34. Preferably, the dielectric layer 34 could include any dielectric material containing oxides, such as the dielectric layer 34 in this embodiment preferably includes an oxide layer deposited by flowable chemical vapor deposition (FCVD) process, an oxide layer deposited by high-density plasma (HDP) process, and another oxide layer composed of tetraethyl orthosilicate (TEOS).

Next, a replacement metal gate (RMG) process is conducted to transform the gate structures 18 into metal gates. The RMG process could be accomplished by first performing a selective dry etching or wet etching process, such as using etchants including ammonium hydroxide (NH₄OH) or tetramethylammonium hydroxide (TMAH) to remove the polysilicon material 22 from gate structures 18 for forming recesses (not shown) in the dielectric layer 34.

Next, a high-k dielectric layer 36 and a conductive layer including at least a U-shaped work function metal layer 38 and a low resistance metal layer 40 are formed in the recesses, and a planarizing process is conducted so that the surfaces of the U-shaped high-k dielectric layer 36, U-shaped work function metal layer 38, low resistance metal layer 40, and dielectric layer 34 are coplanar.

In this embodiment, the high-k dielectric layer 36 is preferably selected from dielectric materials having dielectric constant (k value) larger than 4. For instance, the high-k dielectric layer 36 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 38 is formed for tuning the work function of the later formed metal gates to be appropriate in an NMOS or a PMOS. For an NMOS transistor, the work function metal layer 38 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 38 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 38 and the low resistance metal layer 40, in which the material of the barrier layer may include titanium (Ti), titanium nitride (TiN), tantalum (Ta) or tantalum nitride (TaN). Furthermore, the material of the low-resistance metal layer 40 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity. Next, part of the high-k dielectric layer 36, part of the work function metal layer 38, and part of the low resistance metal layer 40 are removed to forma recess (not shown), and a hard mask (not shown) is formed in the recess so that the top surfaces of the hard mask and dielectric layer 34 are coplanar. The hard mask could be selected from the group consisting of silicon oxide, silicon nitride, silicon oxynitride, and silicon carbon nitride.

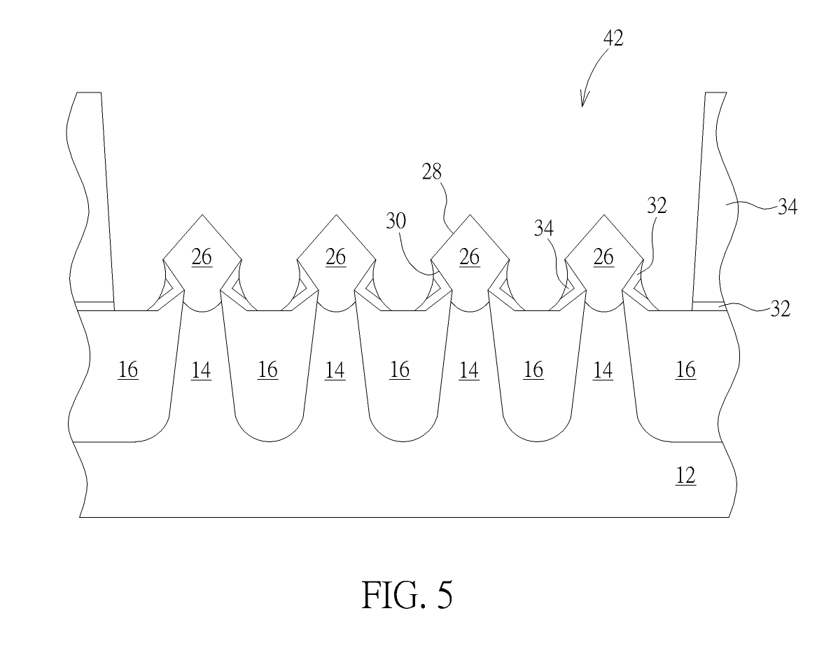

Next, a contact plug formation with salicide process is conducted to form a silicide on the surface of the epitaxial layers 26 and a contact plug electrically connected to the source/drain region and epitaxial layer 26 adjacent to two sides of the gate structure 18. First, as shown in FIG. 5, an etching process, preferably an anisotropic or dry etching is conducted by using a patterned resist (not shown) as mask to remove part of the dielectric layer 34 between gate structures 18 for forming a contact hole 42 exposing the surface of epitaxial layers 26 and part of the STI 16. It should be noted that not all of the dielectric layer 34 and cap layer 32 are removed during the formation of the contact hole 42 so that part of the cap layer 32 and part of the dielectric layer 34 are remained between the V-shaped bottom surfaces 30 of epitaxial layers 26 and the STI 16.

Specifically, the cap layer 32 remained between the V-shaped bottom surface 30 and the STI 16 is V-shaped, and the V-shaped profile of the remaining cap layer 32 forms an approximate 90 degree angle with the V-shaped bottom surface 30 of epitaxial layers 26. Also, the remaining cap layer 32 and the remaining dielectric layer 34 are formed to align to an intersecting point between the reverse V-shaped top surface 28 and V-shaped bottom surface 30 of the epitaxial layers 26.

Next, as shown in FIG. 6, a first metal layer 44 and a second metal layer 46 are deposited in sequence in the contact hole 42, in which the first metal layer 44 and the second metal layer 46 are formed conformally on the surface of the epitaxial layers 46 and inner sidewalls of the contact hole 42. In this embodiment, the first metal layer 44 is selected from the group consisting of Ti, Co, Ni, and Pt, and most preferably Ti, and the second metal layer 46 is selected from the group consisting of TiN and TaN.

After depositing the first metal layer 44 and second metal layer 46, a first thermal treatment process and a second thermal treatment process are conducted sequentially to form a silicide 48 on each of the epitaxial layers 26. In this embodiment, the first thermal treatment process includes a soak anneal process, in which the temperature of the first thermal treatment process is preferably between 500° C. to 600° C., and most preferably at 550° C., and the duration of the first thermal treatment process is preferably between 10 seconds to 60 seconds, and most preferably at 30 seconds. The second thermal treatment process includes a spike anneal process, in which the temperature of the second thermal treatment process is preferably between 600° C. to 950° C., and most preferably at 600° C. and the duration of the second thermal treatment process is preferably between 100 milliseconds to 5 seconds, and most preferably at 5 seconds.

After the two thermal treatment processes are conducted, a third metal layer 50 is deposited to fully fill the contact hole 42. In this embodiment, the third metal layer 50 is composed of tungsten, but not limited thereto. Next, a planarizing process, such as a CMP process is conducted to remove part of the third metal layer 50, part of the second metal layer 46, and part of the first metal layer 44, and depending on the demand of the process also removing part of the dielectric layer 34 for forming a contact plug 52 electrically connected to the epitaxial layers 26. This completes the fabrication of a semiconductor device according to a preferred embodiment of the present invention.

Referring again to FIG. 6, which further illustrates a structural view of a semiconductor device according to a preferred embodiment of the present invention. As shown in FIG. 6, the semiconductor device includes a substrate 12, at least a fin-shaped structure 14 on the substrate 12, a STI 16 on the substrate and surrounding the fin-shaped structures 14, an epitaxial layer 26 disposed on each fin-shaped structure 14, a cap layer 32 and dielectric layer 34 disposed between the epitaxial layer 26 and STI 16, and a contact plug 52 disposed on the epitaxial layers 26 while contacting the STI 16, cap layers 32, and dielectric layers 34 at the same time.

Specifically, each epitaxial layer 26 includes a reverse V-shaped top surface 28 and a V-shaped bottom surface 30, the cap layer 32 and dielectric layer 34 are disposed between the V-shaped bottom surface 30 and the STI 16, in which the dielectric layer 34 contacts the cap layer 32 and both the dielectric layer 34 and cap layer 32 are aligned to an intersecting point between the reverse V-shaped top surface 28 and V-shaped bottom surface 30. The cap layer 32 is preferably V-shaped and the V-shaped profile of the cap layer 32 is situating approximately 90 degrees to the V-shaped bottom surface 30 or forms an approximate 90 degree angle with the V-shaped bottom surface 30 of epitaxial layers 26.

Viewing from an even more detailed perspective, the contact plug 52 includes a first metal layer 44, a second metal layer 46, and a third metal layer 50, and the contact plug 52 contacts the STI 16, the cap layer 32 between the V-shaped bottom surface 30 and the STI 16, and the dielectric layer 34 between the V-shaped bottom surface 30 and the STI 16. The cap layer 32 is preferably a CESL having stress, in which the cap layer 32 is selected from the group consisting of SiN, SiCN, and SiCON.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate;
forming a first fin-shaped structure and a second fin-shaped structure on the substrate;
forming a first epitaxial layer on the first fin-shaped structure and a second epitaxial layer on the second fin-shaped structure; and
forming a cap layer on the first epitaxial layer and the second epitaxial layer, wherein a distance between the first epitaxial layer and the second epitaxial layer is between twice the thickness of the cap layer and four times the thickness of the cap layer.

2. The method of claim 1, further comprising:
forming a shallow trench isolation (STI) on the substrate and around the first fin-shaped structure and the second fin-shaped structure;
forming the first epitaxial layer and the second epitaxial layer on the first fin-shaped structure and the second fin-shaped structure; and
forming the cap layer on the first epitaxial layer, the second epitaxial layer, and the STI.

3. The method of claim 2, wherein the first epitaxial layer comprises a reverse V-shaped top surface and a V-shaped bottom surface.

4. The method of claim 3, further comprising:
forming a dielectric layer on the first epitaxial layer, the second epitaxial layer, and the STI;
removing part of the dielectric layer to form a contact hole to expose the first epitaxial layer, the second epitaxial layer, and part of the STI, wherein part of the cap layer is remained between the V-shaped bottom surface of the first epitaxial layer and the STI.

5. The method of claim 4, wherein the cap layer remained between the V-shaped bottom surface of the first epitaxial layer and the STI is V-shaped.

6. The method of claim 4, further comprising forming a contact plug in the contact hole, wherein the contact plug contacts the STI and the cap layer between the V-shaped bottom surface of the first epitaxial layer and the STI.

7. The method of claim 4, further comprising remaining part of the dielectric layer between the V-shaped bottom surface of the first epitaxial layer and the STI.

8. The method of claim 7, further comprising forming a contact plug in the contact hole, wherein the contact plug contacts the STI and the dielectric layer between the V-shaped bottom surface of the first epitaxial layer and the STI.

9. A semiconductor device, comprising:
a substrate;
a fin-shaped structure on the substrate;
a shallow trench isolation (STI) on the substrate and around the fin-shaped structure;
an epitaxial layer on the fin-shaped structure, wherein the epitaxial layer comprises a reverse V-shaped top surface and a V-shaped bottom surface;
a cap layer between the epitaxial layer and the STI and contacting the V-shaped bottom surface of the epitaxial layer;
a dielectric layer between the V-shaped bottom surface of the epitaxial layer and the STI; and
a contact plug on the epitaxial layer and contacting the STI, the dielectric layer and the cap layer at the same time.

10. (canceled)

11. The semiconductor device of claim 9, wherein the cap layer is between the V-shaped bottom surface of the epitaxial layer and the STI.

12. The semiconductor device of claim 9, wherein the cap layer is V-shaped.

13. (canceled)

14. The semiconductor device of claim 9, wherein the dielectric layer contacts the cap layer directly.

15. The semiconductor device of claim 9, further comprising the contact plug on the epitaxial layer and contacting the STI and the dielectric layer between the V-shaped bottom surface of the epitaxial layer and the STI.

16. The semiconductor device of claim 9, further comprising the contact plug on the epitaxial layer and contacting the STI and the cap layer between the V-shaped bottom surface of the epitaxial layer and the STI.

17. The semiconductor device of claim 9, wherein the cap layer is selected from the group consisting of SiN, SiCN, and SiCON.
